(19) United States
(12) Patent Application Publication
(10) Pub. No.: US 2009/0257272 A1
(43) Pub. Date: Oct. 15, 2009

(54) REDUCED SIZE CHARGE PUMP FOR DRAM SYSTEM

(76) Inventors: Benjamin J. Stembridge, Houston, TX (US); Chia-Jen Chang, Houston, TX (US)

Correspondence Address: NORTH AMERICA INTELLECTUAL PROPERTY CORPORATION, P.O. BOX 506, MERRIFIELD, VA, 22116, US

(21) Appl. No.: 12/100,424

(22) Filed: Apr. 10, 2008

(51) Int. Cl. G11C 11/4074; G11C 5/14

(52) U.S. Cl. 365/149; 365/226

(57) ABSTRACT

A memory system includes: a memory array, comprising a plurality of memory banks, respectively enabled by a plurality of bank enable signals; a bank selector circuit, for generating the plurality of bank enable signals; a plurality of charge pump components, coupled between the plurality of memory banks and the bank selector circuit, and respectively enabled by the plurality of bank enable signals; and a charge pump circuit, coupled to the plurality of charge pump components, for regulating a supply voltage required by the memory system.

### BACKGROUND OF THE INVENTION

1. Field of the Invention

The present invention relates to DRAM systems, and more particularly to a DRAM system having a reduced size charge pump.

2. Description of the Prior Art

In a multi-bank DRAM system, independent banks share data lines and addresses. A bank enable signal controls which bank has charge of the data lines. Banks can also be active simultaneously, provided they are enabled in a sequential fashion.

Conventional DRAM systems utilize charge pumps in a spine region (non-memory array region) of the DRAM to provide current for memory core operations to allow charge sharing between memory cells and bit lines. The charge pump needs to be pumped up to a high voltage for supplying current to the memory bank. In a worst case, 15˜20 mA is required, requiring a voltage supply of 30˜50 mV.

The charge pump is coupled to a detector circuit, for detecting the amount of charge stored in the charge pump. When the potential goes below a lower threshold the charge pump is pumped to increase the potential and charged down when the potential is above an upper threshold. For larger charge pumps, a response time between the detector and the charge pump will be significant. A time to charge the charge pump to a correct supply voltage, due to the large size of the charge pump capacitor, can slow down the operation of the DRAM.

It is therefore desirable to reduce the size of the charge pump.

### SUMMARY OF THE INVENTION

The present invention provides an apparatus and method for reducing the size of a charge pump in a DRAM system.

A memory system is provided, comprising: a memory array, comprising a plurality of memory banks, respectively enabled by a plurality of bank enable signals; a bank selector circuit, for generating the plurality of bank enable signals; a plurality of charge pump components, coupled between the plurality of memory banks and the bank selector circuit, and respectively enabled by the plurality of bank enable signals; and a charge pump circuit, coupled to the plurality of charge pump components, for regulating a supply voltage required by the memory system.

A method for supplying current to a memory array comprising a plurality of memory banks is also provided. The method comprises: providing a supply voltage; generating a bank enable signal for enabling at least a memory bank of the plurality of memory banks; utilizing the bank enable signal to boost the supply voltage; and providing the boosted supply voltage to a memory bank corresponding to the bank enable signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a memory system according to an exemplary embodiment of the present invention.

### DETAILED DESCRIPTION

The present invention provides a system and method for reducing the size of a charge pump in a DRAM system.

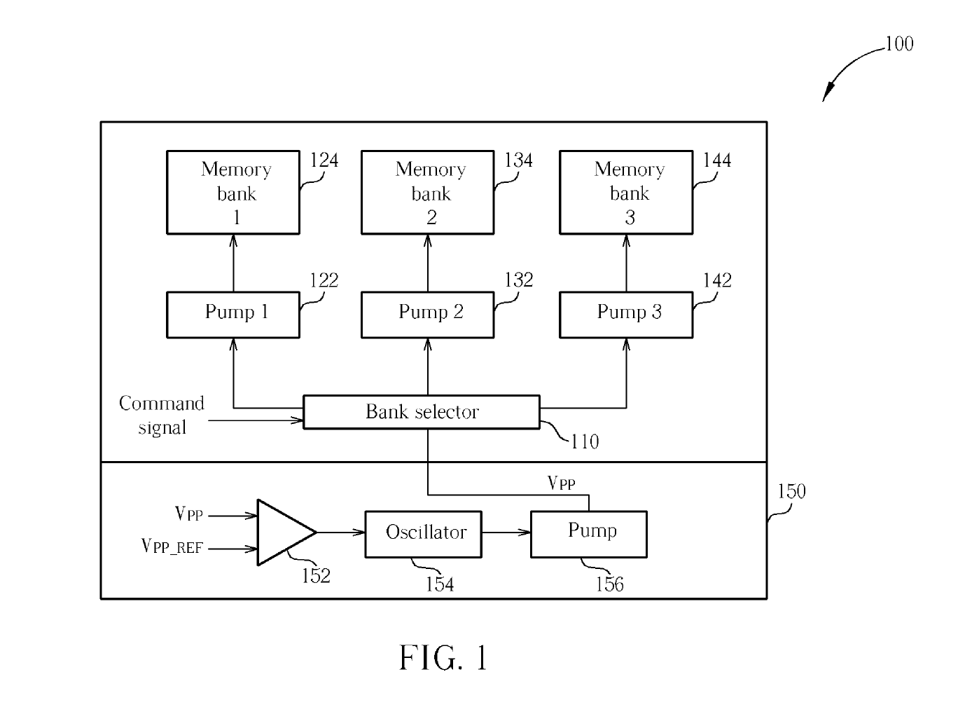

Please refer to FIG. 1. FIG. 1 is a diagram of a multiple bank memory system 100 according to an exemplary embodiment of the present invention. For simplicity only three memory banks 124, 134, 144 are shown in this diagram. The memory system 100 includes a charge pump 156 located in a spine area 150 of the memory system 100, which is considerably smaller than a charge pump in a conventional DRAM system. The charge pump 156 is coupled to a detector circuit 152 and an oscillator 154, for regulating a voltage of the charge pump 156.

The main memory array includes a bank selector circuit 110, for generating a plurality of bank enable signals in response to command signals such as read/write/erase. When a specific memory bank needs to be accessed by the memory system 100, the bank selector 110 will output a bank enable signal corresponding to the specific bank, for activating the specific bank.

The memory system 100 comprises a plurality of charge pump components 122, 132, 142, directly coupled to the memory banks 124, 134, 144 respectively and the bank selector 110. The charge pump components 122, 132, 142 are provided with a supply voltage from the charge pump 156 in the spine. The charge pump components 122, 132, 142 can be boost capacitors, or similar devices for boosting a supply voltage from the charge pump 156.

The charge pump components 122, 132, 142 supply a boost that can be controlled according to a size of capacitance of each charge pump component. The size of capacitance is optimized according to a required current load. Each charge pump component can also include fuse components or switches, for selectively decoupling at least a capacitor in order to calibrate a current supplied to a corresponding memory bank. The current consumed at the memory bank is thereby the same as in the conventional art, but is supplied locally instead of being supplied from the spine region 150. The supply voltage is regulated by the charge pump 156 in the spine region 150, but the size of the charge pump 156 is smaller than in the conventional art.

The charge pump components 122, 132, 142 are directly connected to the memory banks 124, 134, 144 and are enabled by a corresponding bank enable signal from the bank selector 110. When a bank enable signal goes high, one side of a corresponding charge pump component will equal zero, and the other side will output a charge corresponding to a supply voltage required by the memory bank.

As the charge pump components 122, 132, 142 are enabled by the bank enable signal, a current can be directly supplied to a required memory bank, without necessitating charging the whole memory bank system. As the current is supplied locally, rather than in the spine region 150, a time for supplying the current can also be faster than in the conventional art. The placing of local charge pump components close to the memory array allows a smaller charge pump 156 to be utilized in the spine 150 of the DRAM. The present invention therefore reduces costs while improving efficiency.

Those skilled in the art will readily observe that numerous modifications and alterations of the device and method may be made while retaining the teachings of the invention.

What is claimed is:

1. A memory system comprising:
a memory array, comprising a plurality of memory banks, respectively enabled by a plurality of bank enable signals;
a bank selector circuit, for generating the plurality of bank enable signals;
a plurality of charge pump components, coupled between the plurality of memory banks and the bank selector circuit, and respectively enabled by the plurality of bank enable signals; and
a charge pump circuit, coupled to the plurality of charge pump components, for regulating a supply voltage required by the memory system.

2. The memory system of claim 1, wherein the plurality of charge pump components are boost capacitor circuits.

3. The memory system of claim 2, wherein a size or number of the plurality of booster capacitors is according to required current load of the memory system.

4. The memory system of claim 3, wherein each charge pump component contains a fuse component for adjusting a current load of the memory system.

5. The memory system of claim 1, wherein the charge pump circuit is located in a spine region of the memory system.

6. A method for supplying current to a memory array, the memory array comprising a plurality of memory banks, the method comprising:
providing a supply voltage;
generating a bank enable signal for enabling at least a memory bank of the plurality of memory banks;
utilizing the bank enable signal to boost the supply voltage; and
providing the boosted supply voltage to a memory bank corresponding to the bank enable signal.

7. The method of claim 6, wherein the step of utilizing the bank enable signal to boost the supply voltage comprises:
inputting the supply voltage to a boost capacitor circuit.

8. The method of claim 7, further comprising:
selectively decoupling at least a boost capacitor in the boost capacitor circuit according to required current load of the system.

9. The method of claim 8, comprising:
providing at least a fuse component in the boost capacitor circuit; and
utilizing the fuse component to selectively decouple at least a boost capacitor according to required current load of the system.

10. The method of claim 6, wherein the supply voltage is provided in a spine region of the memory system.
